(19) United States
(12) Patent Application Publication
(10) Pub. No.: US 2024/0421107 A1
(43) Pub. Date: Dec. 19, 2024

(54) MOUNTING STRUCTURE

(71) Applicant: Nippon Telegraph and telephone Corporation, Tokyo (JP)

(72) Inventor: Hiromasa Tanobe, Tokyo (JP)

(21) Appl. No.: 18/706,307

(22) PCT Filed: Nov. 10, 2021
(86) PCT No.: PCT/JP2021/041286

§ 371 Date: Apr. 30, 2024

(51) Int. Cl. H01L 23/66; H01L 23/047; H01L 23/14

(52) U.S. Cl. CPC H01L 23/66; H01L 23/047; H01L 23/142

(57) ABSTRACT

An embodiment is a mounting structure including a high-frequency package and a mounting substrate on which the high-frequency package is mounted. In an area of a portion where a first signal lead pin and a second signal lead pin are in contact with the package housing on the bottom surface side, a recess is provided in the package housing. The recess toward the inside of the package housing up to a portion before the connection portion between the signal lead pins and the package conductor layer in the arrangement region of the signal lead pins on the side face of the package housing on the tip side of the signal lead pins.

### CROSS-REFERENCE TO RELATED APPLICATIONS

This application is a national phase entry of PCT Application No. PCT/JP2021/041286, filed on Nov. 10, 2021, which application is hereby incorporated herein by reference.

### TECHNICAL FIELD

The present invention relates to a mounting structure including a high-frequency package and a mounting substrate.

### BACKGROUND

In recent development of optical communication modules of more than 800 Gbps and 1 Tbps and development of a connection technology, which is in progress in parallel with the development of optical communication modules, for connection with mounting substrates on which the modules are mounted, optimization of a mounting mechanism capable of propagating a high-frequency signal with low loss and low reflection is one of major technical problems in recent years.

High-frequency packages constituting optical communication modules have various modes including a mode provided with a high-frequency lead pin that is physically and mechanically separated from a power supply line and a low-speed control signal line. This mode has a feature of relatively facilitating direct introduction of a high-frequency technology to the lead pin, and further, has a feature in which the lead pin functions as a kind of spring mechanism after the high-frequency package is mounted on the mounting substrate. Due to such a mechanical feature, the above-mentioned configuration enables the lead pin to absorb mechanical thermal stress generated by an increase in temperature of the high-frequency package or the mounting substrate after power supply, thereby easily obtaining desired high-frequency characteristics with high reliability at low cost. For this reason, a high-frequency package including a lead pin having the above-described configuration has been used in an optical communication system for a long time.

### CITATION LIST

### Patent Literature

Patent Literature 1: JP 4934733 B2

### Non Patent Literature

Non Patent Literature 1: Implementation Agreement for Integrated Dual Polarization Intradyne Coherent Receivers, IA #OIF-DPC-RX-01.2, Nov. 14, 2013.
Non Patent Literature 2: Chang Fei Yee, “Key high-speed connector layout techniques”, [searched on Oct. 22, 2021] (https://www.edn.com/key-high-speed-connector-layout-techniques/).

### SUMMARY

### Technical Problem

However, the size and position of the lead pin to be mounted using solder, which should be satisfied by the package mounted on the mounting substrate, are determined by the standardization organization such as the “Optical Internetworking Forum”, and the interval between the lead pins and the shape of each lead pin cannot be freely determined. As described in Non Patent Literature 1, the shape of a high-frequency lead pin is defined (see FIG. 6), and a change in signal ((+), (−)) lead pitch necessary for improving the high-frequency characteristics is not allowed. As described above, there is a problem that a degree of freedom of high frequency design in transmission of a high speed signal is low.

For example, Patent Literature 1 discloses an optical receiver module 700 including: an optical circuit 701 that performs optical signal processing on optical signals input from two input ports 702a and 702b; a DC terminal 703; and an output terminal 704 as illustrated in FIG. 7. However, this technology does not disclose in detail the structure of a plurality of high-frequency lead pins that affects high-frequency characteristics in the optical receiver module including the high-frequency lead pins.

In addition, Non Patent Literature 2 describes the three-dimensional shape of lead pins (see FIG. 8), and it is assumed that the pitch interval of a metal pad on a mounting substrate and the interval of lead pins are the same from a contact surface. A portion exposed to the air has high impedance, and thus, a gap between a ground lead pin and a signal lead pin is desired to be narrowed in the vicinity of the connection portion with the package. However, such a structure is not specifically described and is not mentioned at all.

The present invention has been made to solve the above problems, and an object of the present invention is to, in a package including a high-frequency lead pin, suppress reflection loss at the high-frequency lead pin and to enable propagation of a high-frequency signal with low loss after the package is mounted on a mounting substrate.

### Solution to Problem

A mounting structure according to embodiments of the present invention includes: a high-frequency package; and a mounting substrate on which the high-frequency package is mounted, the high-frequency package including a package housing having a multilayer structure including package insulator layers and package conductor layers alternately stacked that constitute a coplanar line, a signal lead pin disposed on a side of a mounting surface of the package housing, the signal lead pin having a rear end connected to a signal wire of any of the package conductor layers constituting the coplanar line, a ground lead pin disposed on the side of the mounting surface of the package housing, the ground lead pin having a rear end connected to a ground wire of any of the package conductor layers constituting the coplanar line, and a recess formed in an arrangement region of the signal lead pin on a side face of the package housing on a tip side of the signal lead pin, the recess being recessed toward an inside of the package housing up to a portion before a connection portion where the signal lead pin is connected to the package conductor layer, wherein each of the ground lead pin and the signal lead pin includes a first bent portion and a second bent portion in an extension direction from the rear end, each of the ground lead pin and the signal lead pin includes an inclination portion provided between the first bent portion and the second bent portion and a parallel portion provided on another end side with respect to the second bent portion, the inclination portion inclining in a direction away from the bottom surface of the package housing, the parallel portion being parallel to the bottom surface of the package housing, positions of tips of the ground lead pin and the signal lead pin are aligned with each other, the mounting substrate includes a multilayer substrate including substrate insulator layers and substrate conductor layers alternately stacked, and a mounting coplanar line formed on a surface of the multilayer substrate, the signal lead pin is connected to a signal line of the mounting coplanar line, and the ground lead pin is connected to a ground line of the mounting coplanar line.

### Advantageous Effects of Invention

As described above, according to embodiments of the present invention, the recess recessed toward the inside of the package housing is provided in the arrangement region of the signal lead pin on the side face of the package housing on the tip side of the signal lead pin, whereby reflection loss at the high-frequency lead pin can be suppressed and a high-frequency signal can be propagated with low loss with the package including the high-frequency lead pin being mounted on the mounting substrate.

### BRIEF DESCRIPTION OF THE DRAWINGS

FIG. 1 is a perspective view illustrating a configuration of a mounting structure according to a first embodiment of the present invention.

FIG. 2 is a perspective view illustrating the configuration of the mounting structure according to the first embodiment of the present invention.

FIG. 3A is a perspective view illustrating a part of the configuration of the mounting structure according to the first embodiment of the present invention.

FIG. 3B is a perspective view illustrating a part of the configuration of the mounting structure according to the first embodiment of the present invention.

FIG. 4 is a perspective view illustrating a part of the configuration of the mounting structure according to the first embodiment of the present invention.

FIG. 5 is a perspective view illustrating a part of the configuration of the mounting structure according to the first embodiment of the present invention.

FIG. 6 is an explanatory diagram illustrating a configuration of a conventional high-frequency package.

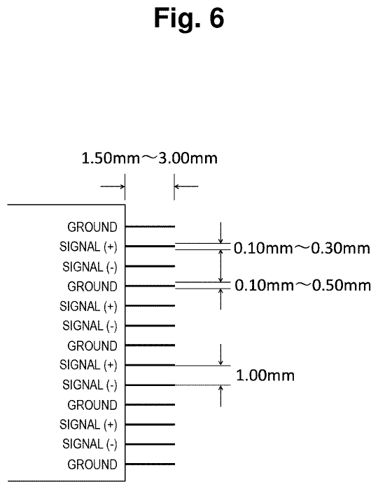

FIG. 7 is a diagram illustrating a configuration of a conventional optical receiver module.

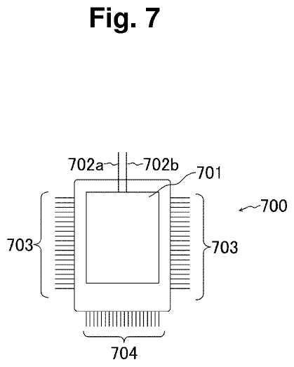

FIG. 8 is a perspective view illustrating a part of the configuration of a conventional high-frequency package.

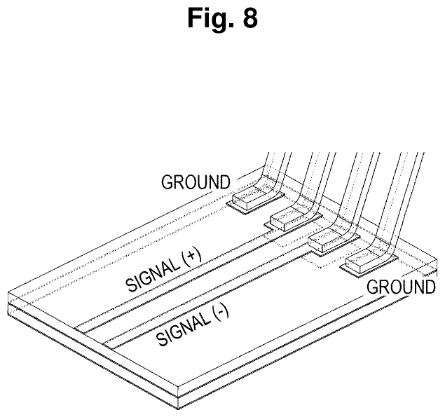

### DETAILED DESCRIPTION OF ILLUSTRATIVE EMBODIMENTS

A mounting structure according to an embodiment of the present invention will be described below.

### First Embodiment

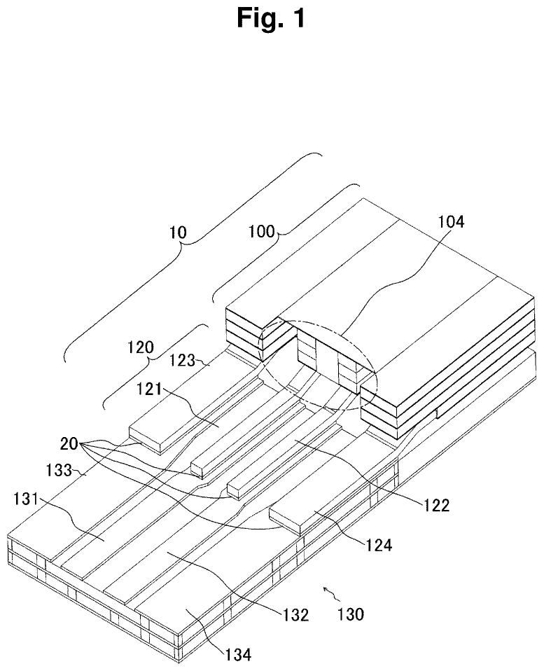

First, a mounting structure according to a first embodiment of the present invention will be described with reference to FIGS. 1, 2, 3A, 3B, and 4. This mounting structure includes a high-frequency package 10 and a mounting substrate 130 on which the high-frequency package 10 is mounted.

The high-frequency package 10 includes a package housing 100 and lead pins 120. The package housing 100 has a multilayer structure including package insulator layers and package conductor layers alternately stacked constituting a coplanar line.

The lead pins 120 are connected to (in contact with) a high-frequency line (not illustrated in FIG. 1) that is provided on the bottom surface (mounting surface) side of the package housing 100 and that includes a signal wire and a ground wire formed in the package conductor layer, and are permanently connected in advance. The high-frequency package 10 is disposed on the upper surface of the mounting substrate 130, and the lead pins 120 are permanently connected to the corresponding wires by solders 20.

In this example, the lead pins 120 include a first ground lead pin 123, a first signal lead pin 121, a second signal lead pin 122, and a second ground lead pin 124, and a high frequency differential transmission structure is achieved in which high-frequency signals propagated through the first signal lead pin 121 and the second signal lead pin 122 have the same intensity and are inverted in phase by 180 degrees.

The signal lead pins (first signal lead pin 121 and second signal lead pin 122) are disposed on the mounting surface side of the package housing 100, and have rear ends connected to signal wires formed in any of the package conductor layers constituting the coplanar line (high-frequency line). The ground lead pins (first ground lead pin 123 and second ground lead pin 124) are disposed on the mounting surface side of the package housing 100, and have rear ends connected to ground wires formed in any of the package conductor layers constituting the coplanar line (high-frequency line). In addition, the positions of the tips of the first signal lead pin 121 and the second signal lead pin 122 are aligned with each other.

The package housing 100 of the high-frequency package 10 has a multilayer structure including package insulator layers 102A, 102B, 102C, and 102D and package conductor layers 101A, 101B, 101C, 101D, and 101E which are alternately stacked. The lead pins 120 are provided on the bottom surface side of the package housing 100 as a signal interface of the high-frequency package 10.

A contact portion where each of the lead pins 120 is in contact with and permanently connected to the package housing 100 is not located on the lowermost bottom surface of the package housing 100. In the present embodiment, the lead pins 120 are in contact with and permanently connected to the package conductor layer 101B which is the second layer from the bottom surface side.

Further, in an area in the vicinity of the portion where the first signal lead pin 121 and the second signal lead pin 122 are in contact with the package housing 100 on the bottom surface side, the package insulator layer and the package conductor layer are selectively removed, so that a recess 104 in appearance is provided in the package housing. The recess 104 is formed to be recessed toward the inside of the package housing 100 up to a portion before the connection portion between the signal lead pins and the package conductor layer in the arrangement region of the signal lead pins on the side face of the package housing 100 on the tip side of the signal lead pins. The outer shape of a space defined by the recess 104 is, for example, a rectangular parallelepiped.

As a further feature, in the area in the vicinity of the portion where the first signal lead pin 121 and the second signal lead pin 122 are in contact with the package housing 100, a conductor removal area 106 formed by selectively removing the package conductor layers 101B and 101C is provided only immediately above the space sandwiched between the first signal lead pin 121 and the second signal lead pin in the thickness direction of the package housing 100. In the present embodiment, a part of the package conductor layers 101C and 101D are selectively removed within the package housing 100.

The mounting substrate 130 includes a multilayer substrate having two substrate insulator layers 137 and 138, a substrate conductor layer 135, and a substrate conductor layer 136. The lowermost substrate conductor layer 136 is grounded, and the substrate conductor layer 135 which is an intermediate layer is at a ground potential. In addition, a first signal line 131, a second signal line 132, a first ground line 133, and a second ground line 134 are formed by patterning the uppermost substrate conductor layer, and these lines constitute a mounting coplanar line. The substrate conductor layer 136 and the substrate conductor layer 135 are electrically connected by a via (ground via) 139 penetrating the substrate insulator layer 138. In addition, the substrate conductor layer 135 is electrically connected to the first ground line 133 and the second ground line 134 by a ground via 139 penetrating the substrate insulator layer 137. Due to the ground via 139, the ground potential of the grounded substrate conductor layer 136 is the same as the ground potential of the other substrate conductor layers and the ground lines.

The signal lead pins (first signal lead pin 121 and second signal lead pin 122) are connected to the signal lines (first signal line 131 and second signal line 132) of the mounting coplanar line described above. In addition, the ground lead pins (first ground lead pin 123 and second ground lead pin 124) are connected to the ground lines (first ground line 133 and second ground line 134) of the mounting coplanar line.

Note that the insulator layers constituting the package housing can be made of alumina ceramics, and the conductor layers constituting the package housing can be made of metal such as titanium or tungsten. In addition, the widths of the ground lead pins at the connection portions with the ground lines of the mounting coplanar line can be set wider than the widths at other portions.

Each of the first ground lead pin 123, the second ground lead pin 124, the first signal lead pin 121, and the second signal lead pin 122 which serve as the lead pins 120 has a first bent portion 125 and a second bent portion 126 on the side close to the package housing 100. The lead pins 120 are inclined toward the lowermost bottom surface of the package by the bending of the first bent portions 125 that are the first bent portions on the side closest to the package housing 100. Each of the ground lead pins and the signal lead pins includes an inclination portion inclined in a direction away from the bottom surface of the package housing 100 between the first bent portion 125 and the second bent portion 126.

Due to the second bent portion 126 which is another bent portion, a lead pin structure is achieved in which the lead pins are substantially aligned with the horizontal plane of the lowermost bottom surface of the package housing 100. In other words, the lead pins 120 include parallel portions parallel to the bottom surface of the package housing 100 on the other end side with respect to the second bent portions 126. It is to be noted that all the lead pins 120 are cut so that their tip positions are aligned.

Further, the package conductor layer (package conductor layer 101B) of the package housing 100 where all the lead pins 120 are in contact with and permanently connected to the package housing 100 is not the lowermost package conductor layer (package conductor layer 101A). In the present embodiment, the lead pins 120 are in contact with and permanently connected to the second package conductor layer from the lowermost package conductor layer.

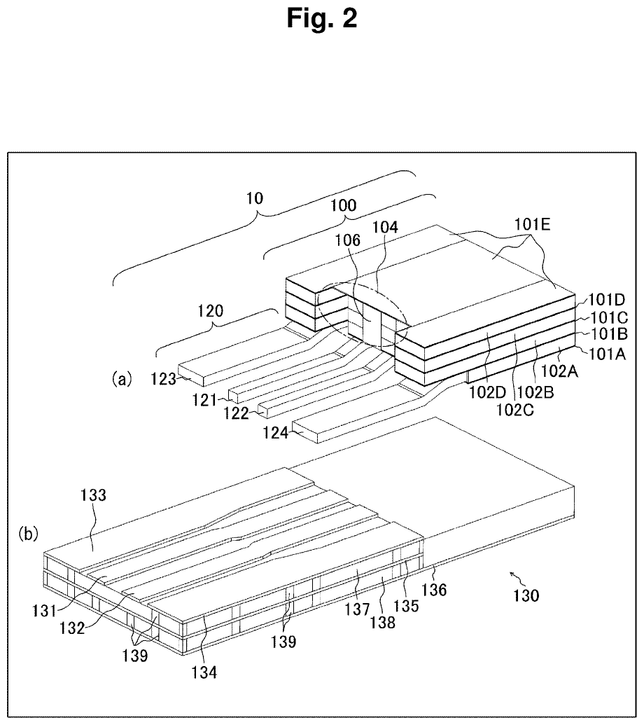

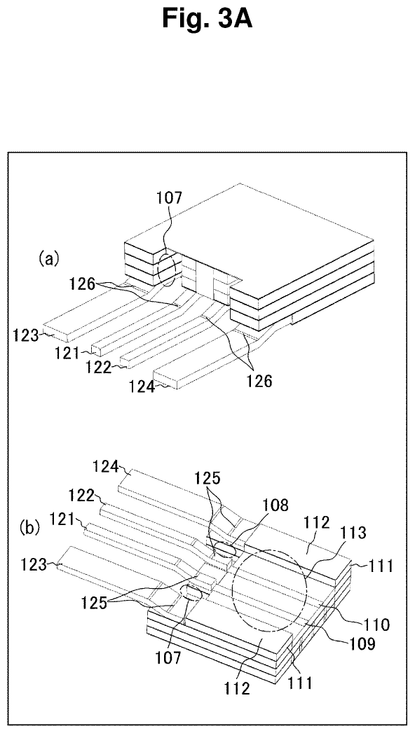

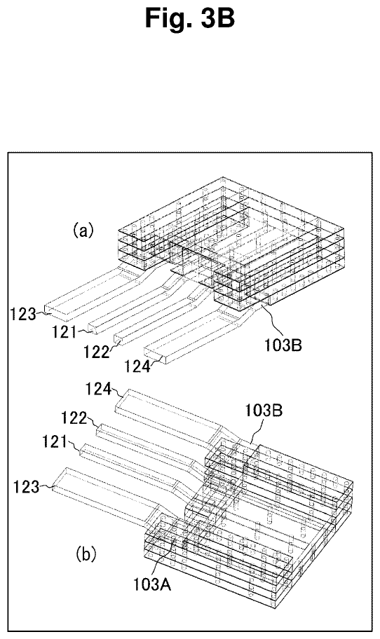

A package insulator layer 111 and a package conductor layer 112 are selectively stacked toward the bottom surface of the package housing 100 on only the package conductor layer with which the first ground lead pin 123 and the second ground lead pin 124 are in contact, and the package conductor layer 112 located at the lowermost bottom surface of the package housing 100 is exposed (FIG. 3A). Note that the package insulator layer 111 is a part of the package insulator layer 102A in FIG. 2, and the package conductor layer 112 is a part of the package conductor layer 101A in FIG. 2.

Note that, on the exposed surface of the further stacked portion obtained by further stacking the layers, the conductor layer is at the ground potential by plating, or the like, and a gap 103A and a gap 103B generated between the end of the further stacked portion and the rear ends of the first ground lead pin 123 and the second ground lead pin 124 are zero or desired tiny gaps (FIG. 3B).

The height positions, in the package housing 100, of the package conductor layer with/to which the first signal lead pin 121 and the second signal lead pin 122 are in contact and permanently connected in the thickness direction are the same as those of the first ground lead pin 123 and the second ground lead pin 124. However, a first signal wire 109 connected to the first signal lead pin 121 and a second signal wire 110 connected to the second signal lead pin 122 have an exposed structure 113 exposed to an external environment (FIG. 3A). The area of the exposed structure 113 is, for example, an area of a groove formed on the bottom surface (mounting surface) side of the package housing 100 and extending in the direction in which the lead pins extend, and at least one package conductor layer is removed. Note that the first signal wire 109 and the second signal wire 110 are differential high-frequency signal lines in which high-frequency signals that have the same signal intensity and that are inverted in phase by 180 degrees can propagate.

In addition, a counterbore portion 107 is provided between portions where the first signal lead pin 121 and the first ground lead pin 123 are connected to the package housing 100. Similarly, a counterbore portion 108 is provided between portions where the second signal lead pin 122 and the second ground lead pin 124 are connected to the package housing 100 (FIG. 3A).

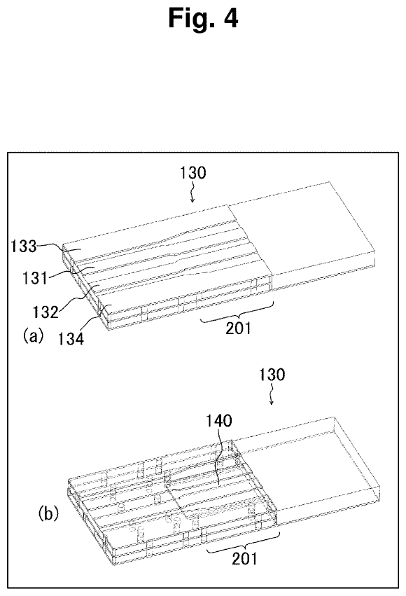

In addition, a removal area 140 from which the substrate conductor layer (substrate conductor layer 135) disposed inside the multilayer substrate is selectively removed is provided in a connection region 201 of the mounting substrate 130 where the lead pins 120 are soldered and connected to the first signal line 131 and the second signal line 132 as illustrated in FIG. 4. The substrate conductor layer 135 that is grounded is not formed below the first signal line 131 and the second signal line 132 in the removal area 140.

With the above-described configuration, all of the lead pins 120, the first signal wire 109, the second signal wire 110, and the mounting substrate 130 can propagate differential high-frequency signals.

Next, the principle will be described. The differential high-frequency signal propagating through the mounting substrate 130 can be propagated without reflection by the removal area 140 that achieves a suppression of a decrease in the differential characteristic impedance at the portion where the lead pins 120 are connected. When the differential high-frequency signal is then propagated through the lead pins 120 to the high-frequency line formed in the package housing 100 located at a position higher than the upper surface of the mounting substrate 130, it is necessary to provide an inclination portion in the lead pins 120 and then connect the lead pins 120 to the package housing 100.

Since air is present around the lead pins 120 in a region from the inclination portions between the first bent portions 125 and the second bent portions 126 of the lead pins 120 to the connection with the package housing 100, the electromagnetic field distribution forming the differential high-frequency signal easily spreads, and discontinuity occurs in the characteristic impedance. The configuration for addressing this problem is the recess 104, the counterbore portion 107, and the counterbore portion 108. The structures described above are set to have the ground potential at desired portions, and this is equivalent to providing a ground wall around the electromagnetic field. The characteristic impedance can be freely designed depending on the distance of the ground wall from the signal line, and at the same time, leakage of the electromagnetic field can be suppressed, and radiation can also be suppressed. By these electrophysical functions, the spread of the electromagnetic field is suppressed, and at the same time, characteristic impedance continuity is provided.

Further, the surfaces of the first signal wire 109 and the second signal wire 110 included in the package housing 100 are partially exposed to the outside, but are not located on the lowermost bottom surface of the package housing 100. In addition, the package insulator layer 111 and the package conductor layer 112 having stable ground potentials are formed on both sides in the longitudinal direction which is the extending direction of the lead pins. The package insulator layer 111 and the package conductor layer 112 electrically act as a ground wall (guard ground structure). As a result, the spread of the electromagnetic field is also suppressed in the package housing 100, and stable signal propagation is enabled. In addition, each of the signal lead pins and the ground lead pins has the same width at the tip portion, and can be arranged at predetermined intervals.

As described above, according to the first embodiment, even when the height positions of the high-frequency signal lines respectively formed in the mounting substrate 130 and the package housing 100 are different, the high-frequency signal can be propagated with low loss without being reflected by the high-frequency lead pin connection mechanism.

### Second Embodiment

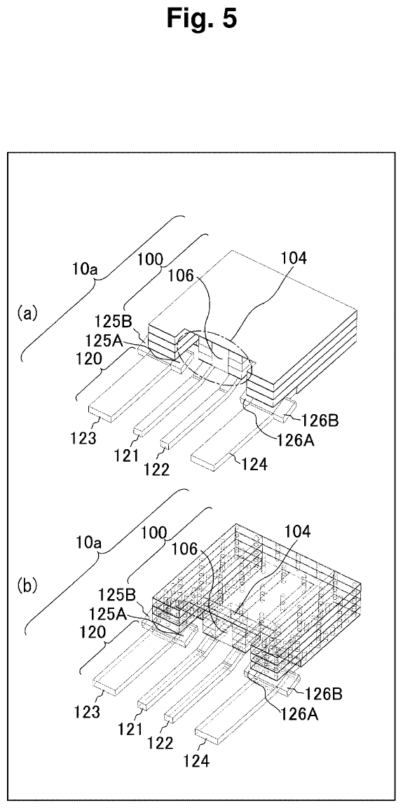

Next, a mounting structure according to a second embodiment of the present invention will be described with reference to FIG. 5. The mounting structure according to the second embodiment also includes a high-frequency package 10a and a mounting substrate on which the high-frequency package 10a is mounted, but the mounting substrate is not illustrated in FIG. 5.

In the high-frequency package 10a in the mounting structure according to the second embodiment, a first ground lead pin 123 includes a structure 125A and a structure 125B obtained by partially increasing the width, and a second ground lead pin 124 includes a structure 126A and a structure 126B obtained by partially increasing the width.

The structures 125A and 125B are provided on an inclination portion of the first ground lead pin 123. The structures 126A and 126B are provided on an inclination portion of the second ground lead pin 124. As described above, in the second embodiment, the width of the ground lead pin in the inclination portion is larger than the width of a signal lead pin in the inclination portion. In this example, the width of the ground lead pin is larger than the width of the signal lead pin as a basic structure, and further, the width of the ground lead pin is much larger than the width of the signal lead pin in the inclination portion as compared with other regions.

In the inclination portion, the structure 125A is provided on the inner side from the first ground lead pin 123 toward the first signal lead pin 121, and the structure 125B is provided on the opposite side. With this configuration, the width of the inclination portion is further increased. In the inclination portion, the structure 126A is provided on the inner side from the second ground lead pin 124 toward the second signal lead pin 122, and the structure 126B is provided on the opposite side. With this configuration, the width of the inclination portion is further increased.

The structures 125A and 126A increased to the inside are used for optimal design of the characteristic impedance at the inclination portions of the lead pins 120. That is, the structures 125A and 126A are used as optimization for lowering the characteristic impedance in the inclination portions of the first signal lead pin 121 and the second signal lead pin 122.

On the other hand, the structure 125B and the structure 126B increased in width to the outside are assumed to be used for generalization when multiple lead pins are arranged in a row, although the present embodiment shows only the lead pins 120 that achieve a set of differential lines. That is, assuming a case where the multiple lead pins 120 are arranged in parallel in either the right or left directions or both the right and left directions in the arrangement direction of the multiple lead pins 120 for handling a multi-lane differential high-frequency signal, the signal lead pins are arranged on both sides of the ground lead pin. The structure 125B and the structure 126B increased to the outside are provided to the configuration described above.

According to the second embodiment, even when the height positions of the high-frequency signal lines formed respectively in the mounting substrate and the package housing 100 are different, the high-frequency signal can be propagated with low loss without being reflected by the high-frequency lead pin connection mechanism.

Meanwhile, it is not necessary to further stack only one layer so as to be adjacent to or in contact with the ground lead pin on the bottom surface side of the package housing, and it is possible to employ a structure including multiple package insulator layers and package conductor layers which are alternately stacked, the package conductor layers being electrically connected using ground vias formed in the package insulator layers. In this case, the high-frequency line provided on the bottom surface side of the package housing is not located in the second package conductor layer from the bottom surface, but includes at least three package conductor layers.

Further, in the above-described embodiment, four package insulator layers and five package conductor layers are used, but it is obvious that the number of the package insulator layers and the number of the package conductor layers are not limited thereto. A plurality of multilayer structures may be further provided on the package conductor layer 101E having the ground potential, and it is obvious that the shapes of the plurality of multilayer structures are freely selected, because the plurality of multilayer structures is a region where the electromagnetic field distribution of the high-frequency signal is extremely small.

In addition, regarding the material, a base material (package insulator layer) constituting most of the structure is made of alumina ceramics in the example described in the embodiments. However, it is obvious that the material is not necessarily limited thereto. For example, aluminum nitride, zirconia, and the like can be applied as ceramic materials, quartz glass and low-melting-point glass can be applied as inorganic materials, and a resin material and a fluororesin material can be applied as organic materials. A material can be appropriately selected and used in consideration of the manufacturing process.

As described above, according to embodiments of the present invention, the recess recessed toward the inside of the package housing is provided in the arrangement region of the signal lead pins on the side face of the package housing on the tip side of the signal lead pins, whereby reflection loss at the high-frequency lead pins can be suppressed and a high-frequency signal can be propagated with low loss with the package including the high-frequency lead pins being mounted on the mounting substrate.

Note that the present invention is not limited to the embodiments described above, and it is obvious that many modifications and combinations can be made by those skilled in the art within the technical idea of the present invention.

### REFERENCE SIGNS LIST

10 high-frequency package
20 solder
100 package housing
101A, 101B, 101C, 101D package conductor layer
102A, 102B, 102C, 102D package insulator layer
103A, 103B gap
104 recess
106 conductor removal area
107, 108 counterbore portion
109 first signal wire
110 second signal wire
111 package insulator layer
112 package conductor layer
113 exposed structure
120 lead pin
121 first signal lead pin
122 second signal lead pin
123 first ground lead pin
124 second ground lead pin
125 first bent portion
126 second bent portion
130 mounting substrate
131 first signal line
132 second signal line
133 first ground line
134 second ground line
135, 136 substrate conductor layer
137, 138 substrate insulator layer
139 via (ground via)
140 removal area
201 connection region

1.-9. (canceled)

10. A mounting structure comprising:
a high-frequency package; and
a mounting substrate on which the high-frequency package is mounted,
the high-frequency package including
a package housing having a multilayer structure including package insulator layers and package conductor layers alternately stacked that constitute a coplanar line,
a signal lead pin disposed on a side of a mounting surface of the package housing, the signal lead pin having a first end connected to a signal wire of any of the package conductor layers constituting the coplanar line, and
a ground lead pin disposed on the side of the mounting surface of the package housing, the ground lead pin having a first end connected to a ground wire of any of the package conductor layers constituting the coplanar line,
the package housing having a recess in an arrangement region of the signal lead pin on a side face of the package housing facing in a direction of a second end of the signal lead pin opposite to the first end, the recess being recessed toward an inside of the package housing up to a portion before a connection portion where the signal lead pin is connected to one of the package conductor layers,
wherein
each of the ground lead pin and the signal lead pin includes an inclination portion provided on a side of the first end via first bent portion and inclining in a direction away from a bottom surface of the package housing, and a parallel portion being parallel to the bottom surface of the package housing, the parallel portion extending from the inclination portion via a second bent portion to a second end opposite to the first end,
positions of tips of the ground lead pin and the signal lead pin are aligned with each other,
the mounting substrate includes
a multilayer substrate including substrate insulator layers and substrate conductor layers alternately stacked, and
a mounting coplanar line on a surface of the multilayer substrate,
the signal lead pin is connected to a signal line of the mounting coplanar line, and
the ground lead pin is connected to a ground line of the mounting coplanar line.

11. The mounting structure according to claim 10, wherein
the package housing further includes a counterbore portion on the side face of the package housing facing in the direction of the second end of the signal lead pin between a connection portion with the signal lead pin and a connection portion with the ground lead pin.

12. The mounting structure according to claim 11, wherein the ground lead pin is wider in a connection portion with the ground line of the mounting coplanar line than in other portions.

13. The mounting structure according to claim 11, wherein the inclination portion of the ground lead pin is wider than the inclination portion of the signal lead pin.

14. The mounting structure according to claim 11, wherein
the signal lead pin is connected to the signal wire of one of package conductor layer other than a package conductor layer on the bottom surface of the package housing,
the ground lead pin is connected to the ground wire of the package conductor layer on the bottom surface of the package housing, and
the package housing includes a groove extending in a direction in which the signal lead pin extends in the mounting surface of the package housing in an arrangement region of the signal lead pin, to form a guard ground structure in which the package conductor layer disposed in the groove and connected to the signal lead pin is disposed between package insulator layers which define a wall surface of the groove.

15. The mounting structure according to claim 11, wherein the package conductor layer connected to the ground lead pin and the package conductor layer in another layer are set at a ground potential.

16. The mounting structure according to claim 11, wherein
the signal lead pin includes a first signal lead pin and a second signal lead pin constituting a differential line, and
at least one of the package conductor layers of the package housing is selectively removed in a region where the first signal lead pin is connected and a region where the second signal lead pin is connected.

17. The mounting structure according to claim 10, wherein the ground lead pin is wider in a connection portion with the ground line of the mounting coplanar line than in other portions.

18. The mounting structure according to claim 10, wherein the inclination portion of the ground lead pin is wider than the inclination portion of the signal lead pin.

19. The mounting structure according to claim 18, wherein the second end of the signal lead pin and the second end of the ground lead pin have a same width at tip portions, and are arranged at predetermined intervals.

20. The mounting structure according to claim 10, wherein
the signal lead pin is connected to the signal wire of one of package conductor layers other than a package conductor layer on the bottom surface of the package housing,
the ground lead pin is connected to the ground wire of the package conductor layer on the bottom surface of the package housing, and
the package housing includes a groove extending in a direction in which the signal lead pin extends in the mounting surface of the package housing in an arrangement region of the signal lead pin, to form a guard ground structure in which the package conductor layer disposed in the groove and connected to the signal lead pin is disposed between package insulator layers which define a wall surface of the groove.

21. The mounting structure according to claim 20, wherein the second end of the signal lead pin and the second end of the ground lead pin have a same width at tip portions, and are arranged at predetermined intervals.

22. The mounting structure according to claim 10, wherein the package conductor layer connected to the ground lead pin and the package conductor layer in another layer are set at a ground potential.

23. The mounting structure according to claim 10, wherein
the signal lead pin includes a first signal lead pin and a second signal lead pin constituting a differential line, and
at least one of the package conductor layers of the package housing is selectively removed in a region where the first signal lead pin is connected and a region where the second signal lead pin is connected.

24. The mounting structure according to claim 10, wherein at least one of the substrate conductor layers of the mounting substrate is removed in a region where the signal lead pin is connected to a signal line of the mounting coplanar line.

25. The mounting structure according to claim 10, wherein at least one of the substrate conductor layers of the mounting substrate is removed in a region where the signal lead pin is connected to a signal line of the mounting coplanar line.

26. A high-frequency package, comprising:
a package housing having a multilayer structure including package insulator layers and package conductor layers alternately stacked constituting a coplanar line; and
lead pins connected to a high-frequency line provided on a bottom surface of the package housing, wherein the lead pins include a first ground lead pin, a first signal lead pin, a second signal lead pin, and a second ground lead pin, and the first signal lead pin and the second signal lead pin are configured to have high-frequency signals propagate through them having the same intensity and being inverted in phase by 180 degrees,
wherein
the package housing includes a recess in an arrangement region of the signal lead pins on a side face of the package housing on a tip side of the signal lead pins, the recess being recessed toward an inside of the package housing,
the recess is up to a portion before a connection portion between the signal lead pins and the package conductor layer, and
each of the lead pins include a first bent portion and a second bent portion on a side close to the package housing, the lead pins being inclined toward a lowermost bottom surface of the package by the first bent portions.

27. The high-frequency package of claim 26, wherein the package housing includes a conductor removal area located immediately above a space between the first signal lead pin and the second signal lead pin, the conductor removal area being defined by the absence of package conductor layers in a region corresponding to a thickness of the package housing.

28. The high-frequency package of claim 26, wherein each of the lead pins include parallel portions parallel to the bottom surface of the package housing on another end side with respect to the second bent portions.

29. The high-frequency package of claim 26, wherein the lead pins are in contact with and connected to a second package conductor layer from a lowermost package conductor layer.
